(19) United States
(12) Patent Application Publication
(10) Pub. No.: US 2007/0202689 A1
(43) Pub. Date: Aug. 30, 2007

(54) Methods of forming copper vias with argon sputtering etching in dual damascene processes

(75) Inventors: Seung-Man Choi, Fishkill, NY (US); Kyoung-Woo Lee, Fishkill, NY (US)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/363,070

(22) Filed: Feb. 27, 2006

(51) Int. Cl. H01L 21/4763

(52) U.S. Cl. 438/637

(57) ABSTRACT

A method of forming a via using a dual damascene process can be provided by forming a via in an insulating layer above a lower level copper interconnect and etching into a surface of the lower level copper interconnect in the via using Argon (Ar) sputtering. Then a trench is formed above a lower portion of the via and an upper level copper interconnect is formed in the lower portion of the via and in the trench using a dual damascene process.

### FIELD OF THE INVENTION

The present invention relates to methods of forming structures in integrated circuits, and more particularly, to methods of forming structures in integrated circuits using dual damascene processes.

### BACKGROUND

The use of copper as a material for interconnection in integrated circuits offers some advantages such as lower resistivity, reduction in the number of metal layers used in the integrated circuit, and/or better reliability compared to other types of metals such as aluminum or aluminum alloys. For example, FIG. 1 is a graph that illustrates exemplary gate delays in integrated circuits as well as typical interconnect delays provided by different materials. As shown in FIG. 1, the use of copper can provide relatively low interconnect delay relative to other types of interconnect materials.

However, use of copper as an interconnect in integrated circuits can be complicated when formed via conventional dry etching as illustrated, for example, in FIG. 2A, where photoresist is formed on a metal layer and etched to provide the interconnect shown in FIG. 2B. In contrast, damascene processing using copper can be provided according to FIGS. 3A-3C. According to FIGS. 3A-3C, a substrate is etched to provide trenches therein and then copper is deposited on the substrate so as to overfill the trenches. The excess copper is then subjected to chemical mechanical polishing (CMP) to provide the copper interconnect shown in FIG. 3C.

The use of copper as an interconnect may call for improved diffusion barrier layers to be used therewith as well as raise the likelihood that copper may contaminate other steps used to fabricate the integrated circuits.

A conventional single damascene process using copper for interconnect is shown in FIGS. 4A-4D. According to FIG. 4A, a substrate 400 includes a lower level of metal interconnect 405 and a via 410 that allows electrical contact between an overlying structure and the metal interconnect 405. As shown in FIG. 4B, copper can be deposited in the via 410. As shown in FIG. 4C, a trench 415 can be formed above the via 410 which can be formed using conventional photolithographic and etching techniques. As shown in FIG. 4D, copper is again deposited in the trench 415 on the via 410 to complete a structure 420 that provides electrical contact between an overlying structure and the lower level of metal interconnect 405. As shown in FIGS. 4A-4D, the via 410 and the trench 415 can be filled separately with copper according to separate single damascene fabrication steps.

Single damascene processes are discussed in, for example, U.S. Pat. No. 6,613,664 entitled “Barbed Vias for Electrical and Mechanical Connection Between Conductive Layers in Semiconductor Devices.”

It is also known to use a dual damascene process to fabricate structures such as those shown above in FIGS. 4A-4D. In particular, FIGS. 5A-5E show a conventional dual damascene process that is commonly referred to as trench first dual damascene. According to FIG. 5A, a photoresist material 505 is deposited on an upper layer 510 which is on a lower layer 515 having a first etch stop layer 520 therebetween. A second etch stop layer 525 is located between the lower layer 515 and a substrate 530 including a lower copper interconnect 535.

According to FIG. 5B, the photoresist 505 is used to pattern and etch the upper layer 510 to form a trench 540 that exposes the first etch stop layer 520, whereafter the photoresist 505 is removed. According to FIG. 5C, a second photoresist material 545 is deposited in the trench 540 to define an opening 547 therein through which the lower layer 515 is patterned to form a lower via portion 550 in the trench 540 that exposes the second etch stop layer 525. According to FIG. 5D, the second etch stop layer 525 is removed.

As shown in FIG. 5E, the second photoresist material is removed to define the opening in which copper may be deposited in the via portion 550 and the trench 540 to complete the desired structure. As is well known, however, one of the drawbacks with the “trench first” approach is that if the second photoresist material used to form the lower via portion 550 is misaligned in the trench 540 relative to the copper interconnect 535, the overall size of the via through which an electrical connection may be provided to the lower copper interconnect 535 may be reduced.

It is also known to use what is commonly referred to as a “via first” dual damascene process to create the contact structures described above. As shown in FIG. 6A-6E, a contact structure can be formed by first forming a via as part of the lower structure followed by a trench as an upper part of the structure. According to FIG. 6A, a photoresist 605 is formed on an upper layer 610. A first etch stop layer 620 is formed between the upper layer 610 and a lower layer 615. A second etch stop layer 625 is formed between the lower layer 615 and a copper interconnect 635 in a substrate 630.

As shown in FIG. 6B, a via portion of the contact structure 650 is etched using the photoresist 605 as a mask and a second photoresist 645 is formed on the upper layer 610 to expose the via 650 as shown in FIG. 6C. According to FIG. 6D, the second photoresist 645 is used as an etch mask to form the trench 640 as part of the contact structure on the via 650 to provide the contact structure shown in FIG. 6E. In contrast to the “trench first” dual damascene structure discussed above in reference to FIGS. 5A-5E, misalignment of the trench 640 formed on the via 650 according to the “via first” dual damascene process may allow for misalignment of the trench 640 while still maintaining the overall size of the via 650. Accordingly, the “via first” dual damascene process is sometimes preferred over the “trench first” dual damascene process discussed above.

### SUMMARY

Embodiments according to the invention can provide methods of forming copper vias with argon sputtering etching in dual damascene processes. Pursuant to these embodiments, a method of forming a via using a dual damascene process can be provided by forming a via in an insulating layer above a lower level copper interconnect and etching into a surface of the lower level copper interconnect in the via using Argon (Ar) sputtering. Then a trench is formed above a lower portion of the via and an upper level copper interconnect is formed in the lower portion of the via and in the trench using a dual damascene process.

As appreciated by the present inventors, the use of argon (Ar) sputtering to form recesses in lower level copper interconnects (for anchor structures of vias) may be problematic in that the Ar sputtering may affect the continuity of a liner layer on a horizontal surface of trench above a lower portion of a via. For example, Ar sputtering used to form a recess in a lower level copper interconnect may perforate a liner layer previously formed on a horizontal portion of the trench above the via where the etching is performed. Perforation of the liner layer may allow a subsequently copper material to diffuse into an insulating layer in which the via is formed.

As further appreciated by the present inventors, the Ar sputtering used for etching the recess in the lower level copper interconnect may be performed before the formation of the trench. Rather, the trench can be formed after the Ar sputtering is complete so that the adverse effects on the liner layer at the bottom of the trench can be avoided by performing the argon sputtering before the trench is formed.

In some embodiments according to the invention, a method of forming a via using a dual damascene process can be provided by etching into a surface of a lower level copper interconnect in a via using Ar sputtering before forming a trench above a lower portion of the via. In still further embodiments according to the invention, a method of forming a via using a dual damascene process can be provided by avoiding forming any substantially horizontal surfaces above a bottom of a via before etching into a surface of a lower level copper interconnect in the via using Ar sputtering.

### BRIEF DESCRIPTION OF THE DRAWINGS

FIG. 1 is a graph that illustrates exemplary gate delays in integrated circuits as well as typical interconnect delays provided by different materials.

FIGS. 2A-2B are cross sectional views that illustrate the formation of a via using conventional dry etching.

FIGS. 3A-3C are cross sectional views that illustrate conventional damascene processing.

FIGS. 4A-4D are cross sectional views that illustrate conventional single damascene processing.

FIGS. 5A-5E are cross sectional views that illustrate conventional “trench first” dual damascene processing.

FIGS. 6A-6E are cross sectional views that illustrate conventional “via first” dual damascene processing.

FIGS. 7A-H are cross sectional views illustrating the formation of copper vias including anchor structures using a dual damascene process according to some embodiments of the invention.

FIGS. 8A-8H are cross sectional views illustrating the formation of copper vias including anchor structures formed using dual damascene processes according to some embodiments of the invention.

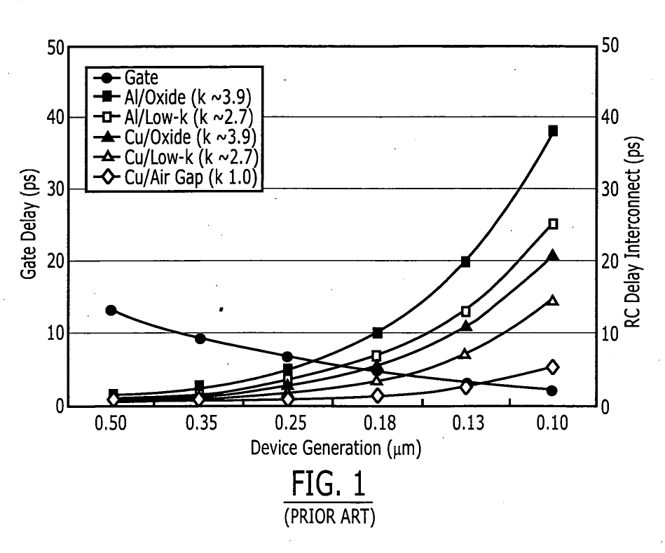

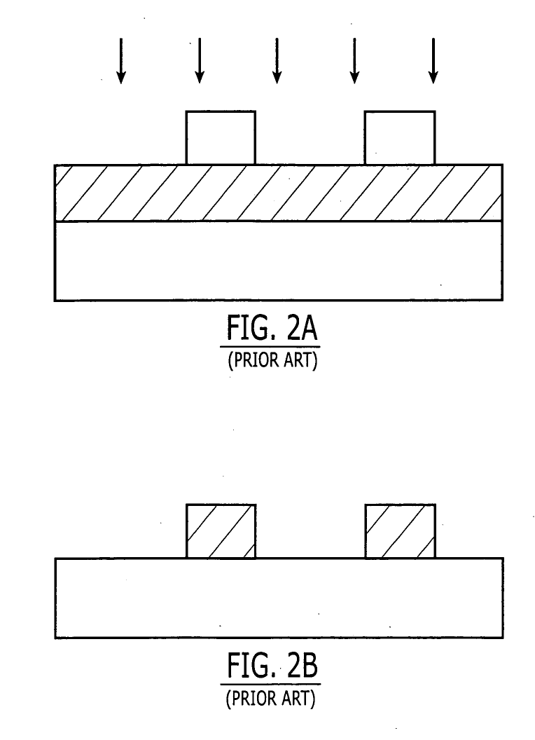

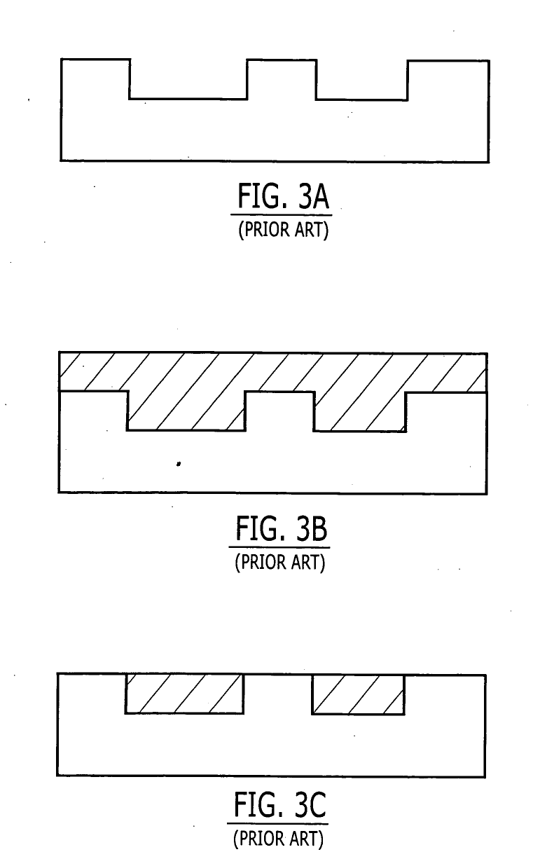

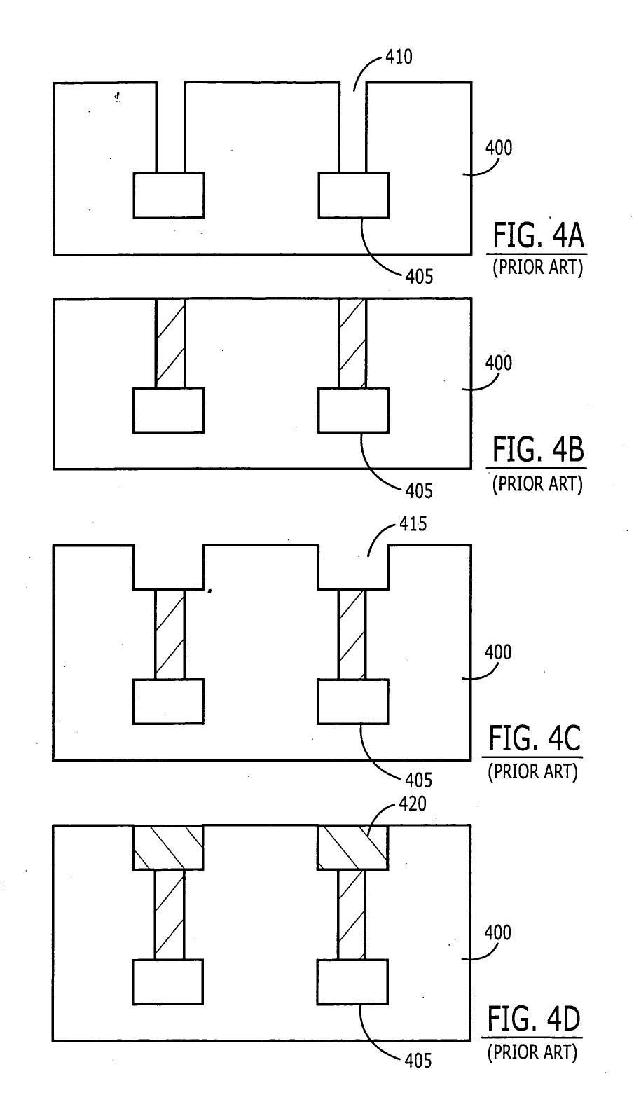

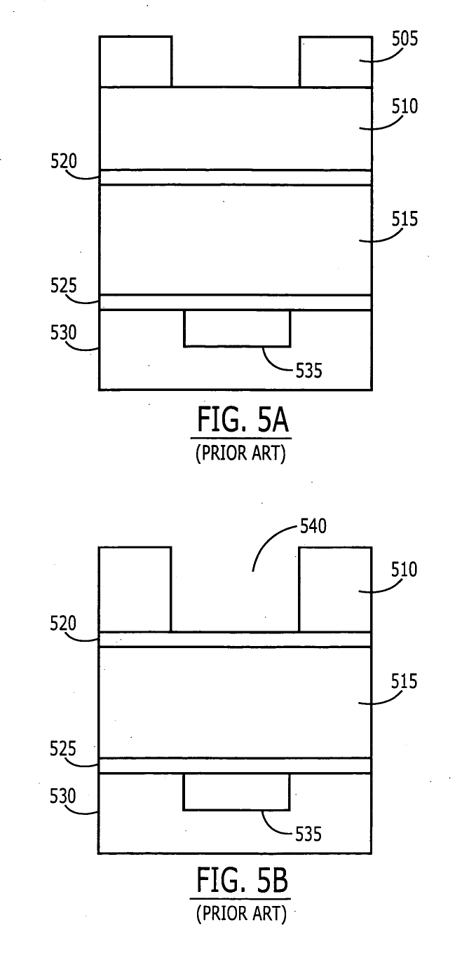

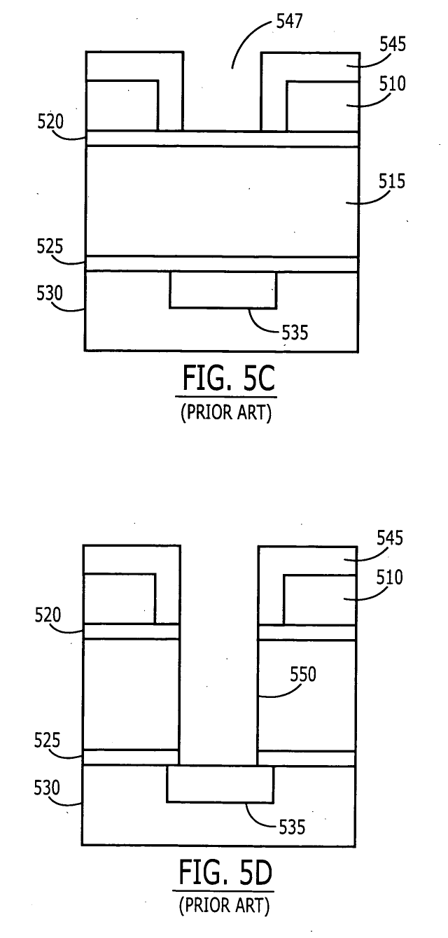

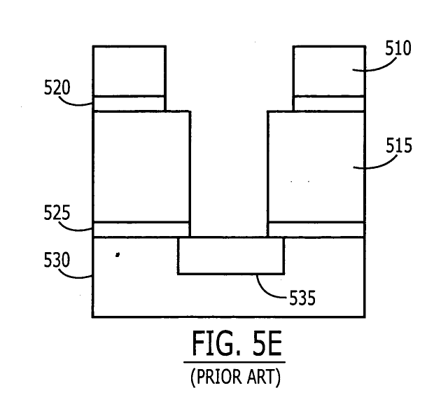

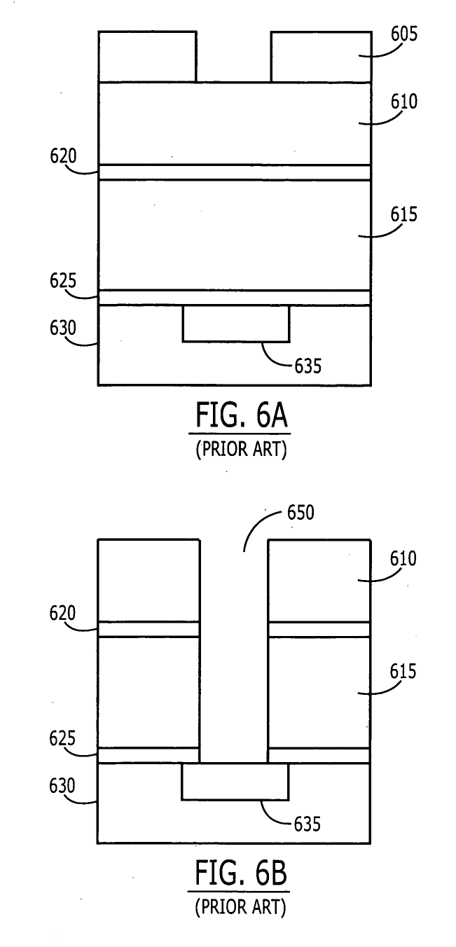

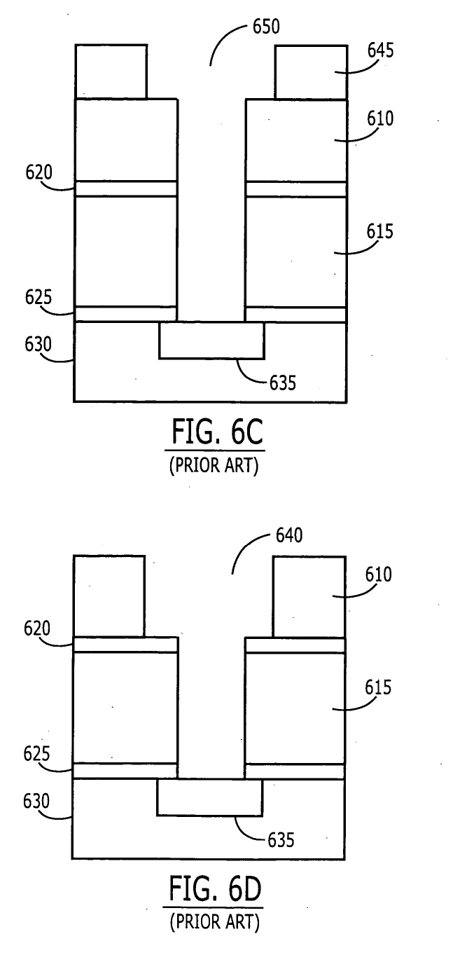

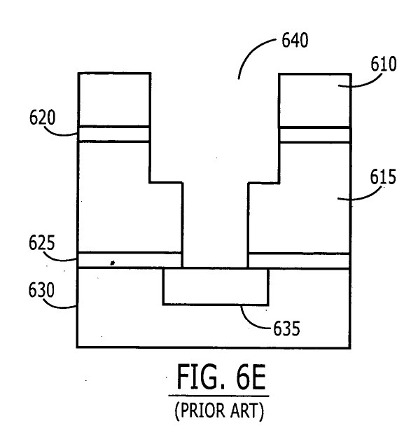

### DESCRIPTION OF EMBODIMENTS ACCORDING TO THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As appreciated by the present inventors, the use of argon (Ar) sputtering to form recesses in lower level copper interconnects (for anchor structures of vias) may be problematic in that the Ar sputtering may affect the continuity of a liner layer on a horizontal surface of trench above a lower portion of a via. For example, Ar sputtering used to form a recess in a lower level copper interconnect may perforate a liner layer previously formed on a horizontal portion of the trench above the via where the etching is performed. Perforation of the liner layer may allow a subsequently formed/deposited copper material to diffuse into an insulating layer in which the via is formed.

As appreciated by the present inventors, the Ar sputtering used for etching the recess in the lower level copper interconnect may be performed before the formation of the trench. Rather, the trench can be formed after the Ar sputtering is complete so that the adverse effects on the liner layer at the bottom of the trench can be avoided by performing the argon sputtering before the trench is formed.

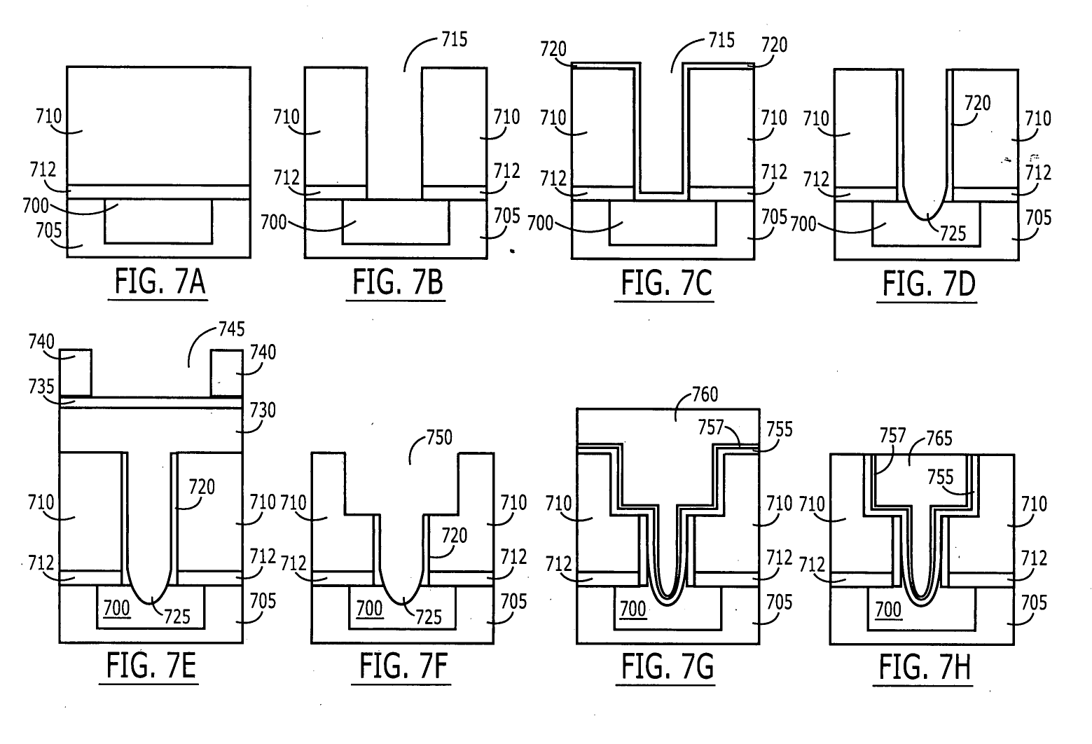

FIGS. 7A-H are cross sectional views that illustrate the formation of copper via structures using a dual damascene process according to some embodiments of the invention. According to FIG. 7A, a lower level copper interconnect 700 is formed in a substrate 705. An etch stop layer 712 can be formed over the lower level copper interconnect 700 and the substrate 705. An inter-metal dielectric (IMD) layer 710 is formed over the etch stop layer 712. In some embodiments according to the present invention, the IMD layer 710 is a dielectric or insulating layer separating the lower level interconnect from the layers above and through which the copper via extends to contact the lower level copper interconnect 700.

According to FIG. 7B, the IMD layer 710 is etched to provide a via 715 including a lower portion through which a surface of the lower level copper interconnect 700 is exposed. According to FIG. 7C, a first liner layer 720 is deposited in the via on the side walls, bottom, and on the exposed surface of the lower level copper interconnect 700. In some embodiments according to the invention, the first liner layer 720 is silicon nitride, silicon carbide, silicon carbon nitride, tantalum, tantalum nitride, and/ or ruthenium formed using a physical vapor deposition, chemical vapor deposition or atomic layer deposition process.

According to FIG. 7D, an Argon (Ar) sputtering etch process is used to etch through the first liner layer 720 and into an underlying surface of the lower level copper interconnect 700 to form a recess 725 therein. It will be understood that the recess 725 is formed to allow for an anchor structure within the lower level copper interconnect 700 that can improve the electrical and mechanical properties of the via structure described herein.

In some embodiments according to the invention, Ar⁺ ions are produced by a direct-current electron bombardment of low pressure argon gas in an ionization chamber. A cathode is at the center of the ionization chamber, with the anode forming a cylindrical outer boundary to a discharge region. An axial magnetic field is applied to the ionization chamber, such that the electrons produced at the cathode have an increased path length and therefore greater ionization efficiency. Argon ions are extracted from the ionization chamber using an acceleration potential between 0-1000 V to provide the etching.

As shown in FIG. 7E, a sacrificial material 730 is formed in the via 715 including in the recess 725 and a hard mask layer 735 is formed thereon. A photoresist pattern 740 is formed on the hard mask layer 735 and includes an opening 745 therein. According to FIG. 7F, portions of the hard mask layer 735, the sacrificial material 730, and the IMD layer 710 that are aligned with the opening 745 in the photoresist 740 are etched to form a trench 750 above a lower portion of the via 715.

According to FIG. 7G, a second liner layer 755 is formed in the trench 750 and in the lower portion of the via 715. In some embodiments according to the invention, the second liner layer 755 is formed of tantalum, tantalum nitride, and/or ruthenium using a physical vapor deposition, chemical vapor deposition or atomic layer deposition process. A copper seed layer 757 is formed in the recess 725 on the second liner layer 755 and an electroplating process can be used to electroplate copper on the copper seed layer 757 to provide a copper material 760 in the lower portion of the via 715 and the trench 750 in a dual damascene process. The entire structure may then be annealed. It will be understood that even though the copper seed layer 757 is shown in FIG. 7G, the copper seed layer 757 may be indistinguishable from the copper material 760.

According to FIG. 7H, the copper material 760 can be planarized using, for example, chemical mechanical polishing, to form the copper via 765 including an anchor structure according to some embodiments of the invention.

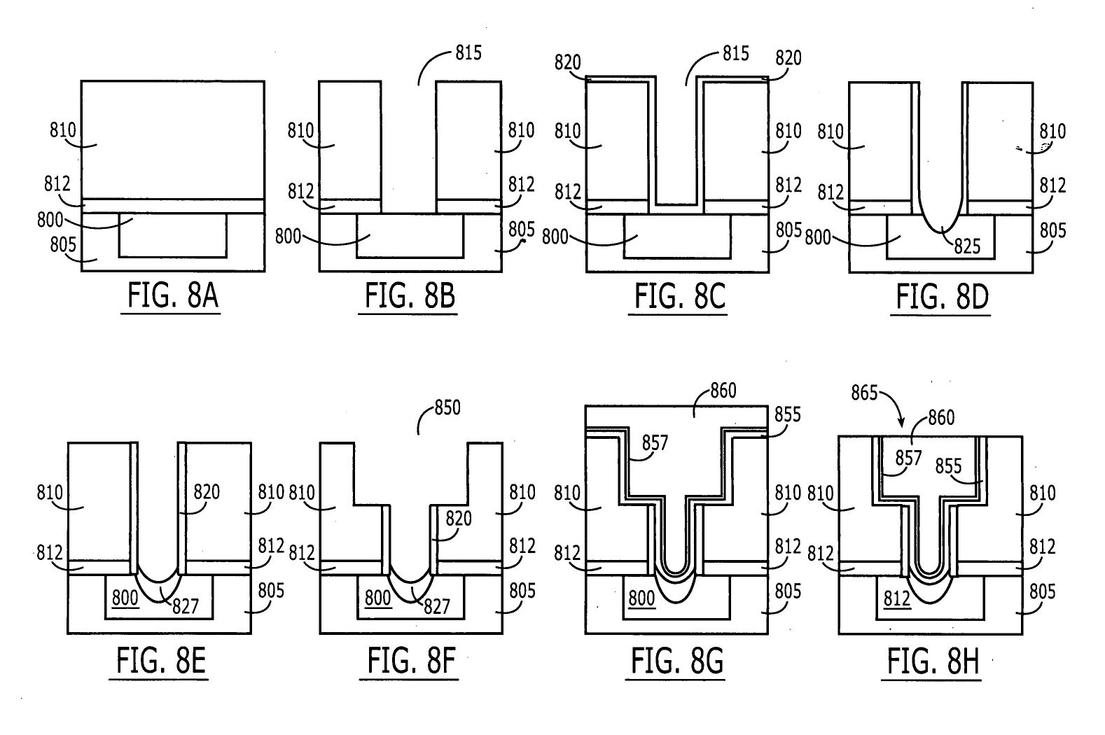

FIGS. 8A-8H are cross sectional views that illustrate methods of forming copper via structures including anchors according to some embodiments of the invention. According to FIG. 8A, a lower level copper interconnect 800 is formed in a substrate 805. An etch stop layer 812 is formed over the substrate 805 including the lower level copper interconnect 800 and an inter-metal dielectric (IMD) layer 810 is formed thereon. According to FIG. 8B, a via 815 is etched through the IMD layer 810 and the etch stop layer 812 to expose a surface of the lower level copper interconnect 800.

According to FIG. 8C, a first liner layer 820 is deposited in the opening 815 including on the side wall thereof and on the exposed surface of the lower level copper interconnect 800. According to FIG. 8D, an Argon (Ar) sputtering etch process is performed to remove the portion of the first liner layer 820 at a bottom of the via 815 and etch into the surface of the lower level copper interconnect 800 to form a recess 825 therein. In some embodiments according to the invention, the Ar sputter etch is provided as described above in reference to FIGS. 7A-7H. According to FIG. 8E, a selective metal deposition is performed to deposit a metal layer 827 in the recess 825. In some embodiments according to the invention, the selective metal deposition can be performed using an electroless process to deposit a cobalt tungsten phosphide layer 827 in the recess 825, which may reduce oxidation of the copper formed thereon during a subsequent ashing process, whereby materials (such as photoresist materials) can be removed using plasma or ultraviolet light generated ozone. In some embodiments according to the invention, the electroless plating is performed without an external source of electricity. A reduction of the metal ions can be accomplished with a reducing agent.

According to FIG. 8F, a photoresist may be formed on a surface of the IMD layer 810 having an opening therein which is used to form a trench 850 above a lower portion of the via 815. Accordingly, the trench 850 is formed after the Ar sputtering process used to form the recess 825, which may help avoid the adverse affects described above as appreciated by the present inventors.

According to FIG. 8G, a second liner layer 855 is formed on a side wall of the trench 850 and the lower portion of the opening 815 including on the metal layer 827 in the recess 825. The second liner layer 855 can be formed of tantalum, tantalum nitride, and/or ruthenium using a physical vapor deposition, chemical vapor deposition or atomic layer deposition process. A copper seed layer 857 is deposited in the via and copper material 860 is electroplated thereon to fill the lower portion of the via 815 and the trench 850 in a dual damascene process. It will be understood that even though the copper seed layer 857 is shown in FIG. 8G, the copper seed layer 857 may be indistinguishable from the copper material 860. According to FIG. 8H, the electroplated copper material 860 is planarized using, for example, chemical mechanical polishing to provide the dual damascene copper via structure 865 including an anchor structure according to some embodiments of the invention.

As described above, the use of argon (Ar) sputtering to form recesses in lower level copper interconnects (for anchor structures of vias) may be problematic in that the Ar sputtering may affect the continuity of a liner layer on a horizontal surface of trench above a lower portion of a via. For example, Ar sputtering used to form a recess in a lower level copper interconnect may perforate a liner layer previously formed on a horizontal portion of the trench above the via where the etching is performed. Perforation of the liner layer may allow subsequently formed copper material to diffuse into an insulating layer in which the via is formed.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed:

1. A method of forming a via using a dual damascene process comprising:
forming a via in an insulating layer above a lower level copper interconnect;
etching into a surface of the lower level copper interconnect in the via using Argon (Ar) sputtering to form a recess therein; and then
forming a trench above a lower portion of the via; and
forming an upper level copper interconnect in the lower portion of the via and in the trench using a dual damascene process.

2. A method according to claim 1 wherein forming a trench above a lower portion of the via comprises forming the trench to include a substantially horizontal surface at a bottom of the trench above the lower portion of the via including a substantially vertical side wall.

3. A method according to claim 1 further comprising:
depositing a metal in the recess.

4. A method according to claim 3 wherein depositing a metal in the recess comprises selectively depositing cobalt tungsten phosphide in the recess directly on the lower level copper interconnect using an electroless plating process.

5. A method according to claim 4 further comprising:
forming a liner layer comprising Ta and/or TaN, using PVD, CVD or ALD on a side wall of the via, a side wall of the trench and in the recess;
forming a copper seed layer on the liner layer;
electroplating copper onto the copper seed layer to fill the via and the trench;
annealing the electroplated copper; and
planarizing the electroplated copper to provide the upper level copper interconnect.

6. A method according to claim 1 further comprising:
forming a liner layer on a side wall of the via before etching the surface of the lower level copper interconnect;
forming a sacrificial material on the side wall of the via and in the recess;
forming a hard mask layer on the sacrificial material;
forming a photoresist pattern including an opening therein on the hard mask layer; and
etching the hard mask layer, the sacrificial material, and insulating layer aligned with the opening to form the trench.

7. A method according to claim 6 wherein forming a liner layer on a side wall of the via comprises forming a first liner layer comprising SiN, SiC, SiCN, Ta, TaN, and/or Ru using PVD, CVD or ALD, the method further comprising:
removing the sacrificial material from inside the trench and via; and
forming a second liner layer comprising TaN and/or Ta on a side wall of the trench, on a side wall of a lower portion of the via and in the recess.

8. A method according to claim 7 further comprising:
forming a copper seed layer on the second liner layer in the recess;
electroplating copper onto the copper seed layer to fill the lower portion of the via and the trench;
annealing the lower level copper interconnect, the second liner layer, and the electroplated copper; and
planarizing the electroplated copper in the trench to provide the upper level copper interconnect.

9. A method according to claim 1 further comprising:
forming a liner layer on a side wall of the via before etching the surface of the lower level copper interconnect;
forming a sacrificial material on the side wall of the via and in the recess; and
forming a hard mask layer on the sacrificial material;
forming a photoresist pattern including an opening therein through which the trench is etched.

10. A method of forming a via using a dual damascene process comprising:
forming a via in an insulating layer above a lower level copper interconnect;
forming a first liner layer in the via;
etching into a surface of the lower level copper interconnect in the via using Ar sputtering to form a recess; and then
forming a trench above a lower portion of the via;
forming a second liner layer on a side wall of the via, a side wall of the trench and in direct contact with the recess; and
forming an upper level copper interconnect on the second liner layer in the lower portion of the via and in the trench above the lower portion of the via using a dual damascene process.

11. A method according to claim 10 further comprising:
forming a sacrificial material in the via before forming the trench;
forming a hard mask layer on the sacrificial material;
forming a photoresist pattern on the hard mask layer including an opening therein; and
etching the hard mask layer, the sacrificial material, and insulating layer aligned with the opening to form the trench.

12. A method according to claim 10 wherein forming a first liner layer in the via comprises forming the first liner layer comprising SiN, SiC, SiCN, Ta, TaN, and/or Ru using PVD, CVD or ALD.

13. A method according to claim 10 wherein forming a second liner layer comprises forming the second liner layer comprising Ta and/or TaN using PVD, CVD or ALD.

14. A method of forming a via using a dual damascene process comprising:
forming a via in an insulating layer above a lower level copper interconnect;
forming a first liner layer in the via;
etching into a surface of the lower level copper interconnect in the via using Ar sputtering to form a recess; and then
selectively depositing a metal layer in the recess;
forming a trench above a lower portion of the via;
forming a second liner layer on a side wall of the via, a side wall of the trench and in direct contact with the selectively deposited metal layer in the recess; and
forming an upper level copper interconnect on the second liner layer in the lower portion of the via and in the trench above the lower portion of the via using a dual damascene process.

15. A method according to claim 14 wherein selectively depositing a metal layer in the recess comprises selectively depositing cobalt tungsten phosphide in the recess directly on the lower level copper interconnect using an electroless plating process.

16. A method according to claim 15 wherein forming a second liner layer comprises forming the second liner layer comprising Ta and/or TaN, using PVD, CVD or ALD on a side wall of the via, a side wall of the trench and in the recess, the method further comprising:
forming a copper seed layer on the second liner layer;
electroplating copper onto the copper seed layer to fill the via and the trench;
annealing the electroplated copper; and
planarizing the electroplated copper to provide the upper level copper interconnect.

17. A method according to claim 14 wherein forming a first liner layer in the via comprises forming the first liner layer comprising SiN, SiC, SiCN, Ta, TaN, and/or Ru using PVD, CVD or ALD.

18. A method of forming a via using a dual damascene process comprising:
etching into a surface of a lower level copper interconnect in a via using Ar sputtering before forming a trench above a lower portion of the via.

19. A method of forming a via using a dual damascene process comprising:
avoiding forming any substantially horizontal surfaces above a bottom of a via before etching into a surface of a lower level copper interconnect in the via using Ar sputtering.
